(19) United States
(12) Patent Application Publication
(10) Pub. No.: US 2022/0402072 A1
(43) Pub. Date: Dec. 22, 2022

(54) ELEMENT CHIP MANUFACTURING METHOD AND SUBSTRATE PROCESSING METHOD

(71) Applicant: Panasonic Intellectual Property Management Co., Ltd., Osaka (JP)

(72) Inventors: Hidefumi SAEKI, Osaka (JP); Hidehiko KARASAKI, Hyogo (JP); Shogo OKITA, Hyogo (JP); Atsushi HARIKAI, Osaka (JP); Akihiro ITOU, Kyoto (JP)

(21) Appl. No.: 17/806,360

(22) Filed: Jun. 10, 2022

(30) Foreign Application Priority Data
Jun. 16, 2021 (JP) 2021-100488

(51) Int. Cl. B23K 26/364; B23K 26/40; H01L 21/78; H01L 21/3065; B23K 26/0622

(52) U.S. Cl. CPC B23K 26/364; B23K 26/40; H01L 21/78; H01L 21/3065; B23K 26/0624

(57) ABSTRACT

An element chip manufacturing method includes a step of preparing a substrate including a semiconductor layer and a wiring layer formed on the semiconductor layer, the substrate having element regions and a dicing region defining the element regions, a laser grooving step of irradiating a laser beam to the wiring layer at the dicing region, to form an aperture exposing the semiconductor layer, and a step of etching the semiconductor layer exposed from the aperture, with plasma, to divide the substrate into a plurality of element chips. The laser grooving step includes a step of irradiating a first laser beam having a first pulse width, to remove the wiring layer in an edge portion of the dicing region, and a step of irradiating a second laser beam having a second pulse width which is longer than the first pulse width, to remove the wiring layer inside from the edge portion.

### CROSS REFERENCE TO RELATED APPLICATION

The present application is based on and claims priority under 35 U.S.C. § 119 with respect to the Japanese Patent Application No. 2021-100488 filed on Jun. 16, 2021, of which entire content is incorporated herein by reference into the present application.

### TECHNICAL FIELD

The present invention relates to an element chip manufacturing method including a step of dicing a substrate including a semiconductor layer with plasma.

### BACKGROUND

As a method of dicing a semiconductor wafer on which a plurality of semiconductor elements are formed, into individual semiconductor elements, Patent Literature 1 (JP2005-191039A) proposes a method of etching the semiconductor wafer by plasma processing, after forming a mask layer on a circuit-forming surface of the semiconductor wafer and patterning the mask layer by laser beam irradiation to form a mask pattern.

In recent years, as a method of manufacturing element chips by dicing a substrate having a wiring layer and a semiconductor layer, there has been developed a technique of etching the semiconductor layer by forming a groove-like aperture (gap) called a street in the wiring layer along a dicing region, and etching the semiconductor layer exposed from the aperture with plasma.

When laser beam irradiation is used for scribing along the dicing region, the beam intensity is reduced in the vicinity of the side walls on both sides of the aperture, as compared to at the bottom of the aperture. As a result, the energy density of the beam in the vicinity of the side walls becomes insufficient, and the melted matter of the wiring layer (hereinafter sometimes referred to as “debris”) tends to adhere to the side walls. When the debris adheres to the side walls, etching proceeds nonuniformly in some cases in the subsequent plasma etching process, which may cause streaks on the chip cross section, leading to a decreased die strength in some cases.

By using an ultrashort pulse laser of picoseconds or femtoseconds for scribing, it is possible to suppress the adhesion of debris. However, a laser oscillator for generating a picosecond laser is more expensive than that for a nanosecond laser. Moreover, although the maximum energy density of the pulse at the peak is large, the pulse width is short, and the output energy per pulse is low. Therefore, the throughput is small, and the processing takes time, resulting in an increased manufacturing cost.

### SUMMARY

One aspect of the present invention relates to an element chip manufacturing method, including: a step of preparing a substrate including a semiconductor layer having a first principal surface and a second principal surface and a wiring layer formed on the semiconductor layer on the first principal surface side, the substrate having a plurality of element regions and a dicing region defining the element regions; a laser grooving step of irradiating a laser beam from the first principal surface side to the wiring layer at the dicing region, to form an aperture exposing the semiconductor layer in the dicing region; and a plasma etching step of etching the semiconductor layer exposed from the aperture, with plasma, the laser grooving step including a first step of irradiating a first laser beam having a first pulse width, to remove the wiring layer in at least an edge portion of the dicing region, and a second step of irradiating a second laser beam having a second pulse width which is longer than the first pulse width, to remove the wiring layer in an inner region inside from the edge portion of the dicing region.

Another aspect of the present invention relates to a substrate processing method for forming an aperture at a predetermined region on a substrate including a semiconductor layer having a first principal surface and a second principal surface and a wiring layer formed on the semiconductor layer on the first principal surface side, the aperture being formed to expose the semiconductor layer, the method including: an irradiation step of irradiating a laser beam from the first principal surface side to the wiring layer at the predetermined region; the irradiation step including a first step of irradiating a first laser beam having a first pulse width, to remove the wiring layer in at least an edge portion of the dicing region, and a second step of irradiating a second laser beam having a second pulse width which is longer than the first pulse width, to remove the wiring layer in an inner region inside from the edge portion of the predetermined region.

According to the present invention, when an aperture is formed in the wiring layer by laser scribing, it is possible to suppress the adhesion of debris on the side surfaces of the aperture, while suppressing the decrease in throughput.

### BRIEF DESCRIPTION OF THE DRAWINGS

FIGS. 1A to 1D are schematic process cross-sectional views illustrating an element chip manufacturing method according to one embodiment of the present disclosure.

FIGS. 2A and 2B are schematic process cross-sectional views illustrating an element chip manufacturing method according to one embodiment of the present disclosure, which show another example of the process shown in FIGS. 1B and 1C.

FIGS. 3A and 3B are schematic process cross-sectional views illustrating an element chip manufacturing method according to one embodiment of the present disclosure, which shows another example of the process shown in FIGS. 1B and 1C.

FIG. 4 is a schematic representation of the configuration of an example of an apparatus for outputting a laser beam.

FIG. 5 is a schematic representation of an example of a plasma processing apparatus used in a dicing step.

FIG. 6A is a top view of a conveying carrier supporting a substrate, and FIG. 6B is a cross-sectional view thereof taken along a line Y-Y.

### DETAILED DESCRIPTION

An element chip manufacturing method according to an embodiment of the present disclosure includes a step of preparing a substrate including a semiconductor layer having a first principal surface and a second principal surface and a wiring layer formed on the semiconductor layer on the first principal surface side. The substrate has a plurality of element regions and a dicing region (street) defining the element regions. The wiring layer may include a circuit layer and a resin layer protecting a surface of the circuit layer. Usually, the circuit layer contains a metal material, and the resin layer contains a resin material. The dicing region is provided like a line in a predetermined pattern, on the first principal surface side of the substrate.

The semiconductor layer is constituted of, for example, silicon (Si), gallium arsenide (GaAs), gallium nitride (GaN), silicon carbide (SiC), and the like.

The wiring layer usually includes a circuit layer, and a resin layer protecting a surface of the circuit layer. The circuit layer contains, for example, a low-k (low dielectric constant) material, a copper (Cu) wiring layer, a metal material, an electrically insulating film (e.g., silicon dioxide, silicon nitride), lithium tantalate (LiTaO₃), lithium niobate (LiNbO₃), and the like. The resin layer contains, for example, a thermosetting resin such as polyimide, a photoresist such as phenol resin, a water-soluble resist such as acrylic resin, and the like.

The element chip manufacturing method includes a laser grooving step of irradiating a laser beam from the first principal surface side to the wiring layer at the dicing region, to form an aperture (gap) exposing the semiconductor layer in the dicing region. This laser grooving step is also called a scribing process or a laser scribing process. The aperture is usually formed like a groove along the line-like dicing region. The width direction of the dicing region is synonymous with the direction of the width of the aperture (gap) formed like a groove, and is the direction orthogonal to the length direction of the street. For effective utilization of the substrate, a smaller width of the groove-like aperture is more preferable. The aperture can be more easily narrowed in width as the verticality of the side surfaces of the wiring layer on both sides of the aperture is enhanced.

The laser grooving step includes a first step of irradiating a first laser beam having a first pulse width, and a second step of irradiating a second laser beam having a second pulse width which is longer than the first pulse width. The second step may be performed before or after the first step.

In the first step of the laser grooving step, the wiring layer in at least an edge portion of the dicing region is removed by irradiation of the first laser beam. The first laser beam is, for example, a picosecond pulse laser, and can process the side surface into a favorable shape. In the second step, the wiring layer in an inner region inside from the edge portion of the dicing region is removed by irradiation of the second laser beam. The pulse width of the second laser beam is longer than that of the first laser beam. The second laser beam is, for example, a nanosecond pulse laser, and is excellent in throughput as compared to the first laser beam. By combining the irradiation of the first laser beam and the irradiation of the second laser beam, it is possible to suppress the adhesion of debris on the side walls of the aperture, while suppressing the reduction in throughput.

When the second step is performed after the first step, in the first step, grooves where the semiconductor layer is exposed can be formed in the edge portions of the dicing region. In the first step, the adhesion of debris on the side walls of the grooves is suppressed by irradiating the first laser beam having a short pulse width. In the subsequent second step, the wiring layer at the inner region surrounded by the grooves at the edge portions is removed by irradiation of the second laser beam. In this way, an aperture with less adhesion of debris can be formed. Furthermore, since the removal of the wiring layer at the inner region is performed with the second laser beam having a pulse width longer than the pulse width of the first laser beam, the reduction in throughput can be suppressed. In addition, the grooves formed in the first step serve to prevent a crack from extending into the element region by the heat generated by irradiation of the second laser beam.

On the other hand, when the second step is performed before the first step, first, an aperture where the semiconductor layer is exposed is formed at the inner region by irradiation of the second laser beam. Since the removal of the wiring layer at the inner region is performed with the second laser beam whose pulse width is longer than the pulse width of the first laser beam, the reduction in throughput can be suppressed. Subsequently, by irradiating the edge portions surrounding the inner region with the first laser beam, the aperture is widened in width, and the debris adhering to the side walls is removed by irradiation of the first laser beam having a short pulse width. The irradiation of the first laser beam in the first step is preferably performed after the irradiation of the second laser beam in the second step, in that an aperture with less adhesion of debris can be obtained.

When the second step is performed before the first step, in the second step, the second laser beam can be irradiated, with the beam center positioned at the inner region. In the subsequent first step, the first laser beam may be irradiated, with the beam center of the first laser beam positioned at the edge portion, in a region sandwiching the region irradiated with the second laser beam. The beam diameter of the first laser beam may be smaller than that of the second laser beam. In this case, the first laser beam irradiated in the first step is irradiated to the side walls of the aperture formed in the second step.

Here, the beam diameter means the diameter of the circle that contains 86% of the beam power (D86 diameter). The circle is centered at the optical axis of the beam and set on a cross section of the beam perpendicular to the optical axis.

When the second step is performed before the first step, the second laser beam is irradiated in the second step, with the beam center positioned at the inner region, and then, in the subsequent first step, the first laser beam may be irradiated, with the beam center positioned at the inner region, so as to include the region having been irradiated with the second laser beam. At this time, by setting the beam diameter of the first laser beam larger than that of the second laser beam, the first laser beam irradiated in the first step is irradiated to the side walls of the aperture formed in the second step, and also to the bottom of the aperture at the inner region. The irradiation of the first laser beam can clean the side walls and the bottom of the aperture, so as to have less adhesion of debris and the like.

In the following, the first laser beam may be referred to as a picosecond pulse laser. It is to be noted, however, that the term of “picosecond pulse laser” does not necessarily mean that the pulse width of the first laser beam is on the order of picoseconds (1 ps or more and less than 1 ns). The pulse width of the first laser beam may be on the order of nanoseconds (1 ns or more) or femtoseconds (less than 1 ps), as long as it is shorter than the pulse width of the second laser beam. In the following, the second laser beam is sometimes referred to as a nanosecond pulse laser, but the term of “nanosecond pulse laser” does not necessarily mean that the pulse width of the second laser beam is on the order of nanoseconds (1 ns or more and less than 1 μs). The pulse width of the second laser beam may be on the order of picoseconds (less than 1 ns), as long as it is longer than the pulse width of the first laser beam.

The pulse width of the first laser beam may be, for example, 100 ps or less, and is preferably 20 ps or less, more preferably 1 ps or less. With the first laser beam having a pulse width of 100 ps or less, it is easy to remove the debris adhering to the side walls of the aperture, and suppress the adhesion of debris. The pulse width of the first laser beam is preferably 500 fs or more, in terms of suppressing an increase in the equipment cost of the laser generator.

The pulse width of the second laser beam is, for example, 10 ns or more. With the second laser beam having a pulse width of 10 ns or more, it is possible to improve the throughput when forming an aperture.

The pulse width of the second laser beam may be 500 ns or less, and may be 200 ns or less, in terms of reducing the heat influence by laser irradiation.

The laser grooving step is followed by a plasma etching step of etching the semiconductor layer exposed from the aperture with plasma, and the substrate is individualized. In the plasma etching step, the semiconductor layer exposed from the formed aperture is etched with plasma until reaching the second principal surface. The semiconductor layer at the element regions is masked with the wiring layer. Therefore, the semiconductor layer at the dicing region exposed from the aperture is etched with plasma. In this way, the substrate is divided into a plurality of element chips having the element regions.

When the verticality of the side surfaces of the wiring layers on both sides of the aperture is insufficient, in etching the semiconductor layer with plasma, the side walls of the formed element chips are disordered, and the die strength of the element chips tend to decrease. On the other hand, by improving the verticality of the side surfaces of the wiring layer to improve the quality of the aperture, the side walls of the semiconductor layer etched with plasma are less likely to be disordered, and high-quality element chips having excellent die strength can be obtained. Furthermore, as the verticality of the side surfaces of the wiring layer improves, the width of the groove-like aperture can be narrower (smaller), and the loss of the substrate can be reduced.

When plasma etching is utilized for individualization of the substrate, it is also necessary to pay attention to the contamination on the side walls and the bottom of the aperture or groove. For example, when the wiring layer includes a circuit layer and a resin layer protecting the circuit layer, with a laser beam having a Gaussian or a top-hat distribution whose intensity is restricted in order to reduce the processing damage on the semiconductor layer, a sufficient energy density for ablating the layer cannot be obtained at the beam end, and the resin becomes liquefied and round in shape due to surface tension, tending to cause a resin ball to adhere as debris, at the end portions of the bottom of the aperture.

The resin ball will not be so problematic when the semiconductor layer is mechanically diced with a blade or the like. However, when the semiconductor layer is etched with plasma, the resin ball will become an obstacle to the reaction between the plasma and the semiconductor layer. As a result, the side walls of the semiconductor layer etched with plasma tend to be disordered, and the quality of the element chips deteriorates in some cases.

According to the method of the present disclosure, however, since the adhesion of the resin ball or debris to the side walls of the aperture is suppressed in the laser grooving step, in the subsequent individualization step, the disorder of the side walls of the semiconductor layer etched with plasma can be suppressed. For example, vertical streaks are suppressed from appearing on the side walls of the semiconductor layer etched with plasma. As a result, high-quality element chips having excellent die strength can be obtained. Furthermore, since the side surfaces of the semiconductor layer can be etched to be more nearly vertical, the width of the aperture (width of the dicing region) can be reduced.

The method of the present disclosure is not limited to the use for manufacturing element chips, and is applicable for forming an aperture by laser processing on a substrate having a semiconductor layer on which a wiring layer is formed. The substrate processing method of the present embodiment is for forming an aperture at a predetermined region on a substrate including a semiconductor layer having a first principal surface and a second principal surface and a wiring layer formed on the semiconductor layer on the first principal surface side, the aperture being formed to expose the semiconductor layer. The method includes an irradiation step of irradiating a laser beam from the first principal surface side to the wiring layer at the predetermined region. The irradiation step includes a first step of irradiating a first laser beam having a first pulse width, to remove the wiring layer in at least an edge portion of the dicing region, and a second step of irradiating a second laser beam having a second pulse width which is longer than the first pulse width, to remove the wiring layer in an inner region inside from the edge portion of the dicing region. In this way, it is possible to form an aperture with less adhesion of debris, while maintaining a high throughput.

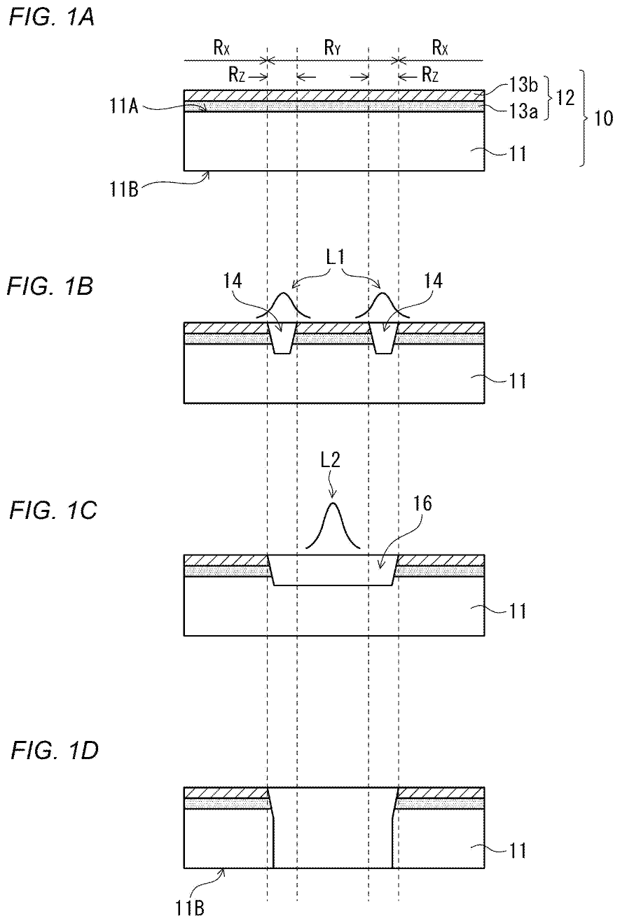

FIGS. 1A to 1D are schematic process cross-sectional views illustrating an element chip manufacturing method according to one embodiment of the present disclosure, which particularly show an example of the laser grooving step.

First, as shown in FIG. 1A, a substrate 10 is prepared (preparation step). The substrate 10 includes a semiconductor layer 11 having a first principal 11A and a second principal surface 11B, and a wiring layer 12 formed on the semiconductor layer 11 on the first principal surface 11A side. The wiring layer 12 includes, for example, a circuit layer 13a and a resin layer 13b protecting the circuit layer. The substrate 10 includes a plurality of element regions Rx and a dicing region Ry defining the element regions Rx. The dicing region Ry has an edge portion Rz provided at a boundary portion with the element region Rx. The edge portions Rz adjacent to different element regions are spaced apart from each other.

Next, as illustrated in FIG. 1B, the first laser beam L1 is irradiated to the edge portion Rz of the dicing region Ry, to remove the wiring layer in the edge portion of the dicing region (first step). This can form a groove 14 along the edge portion Rz. The first laser beam L1 may be a laser beam having a Gaussian distribution. Given that the width of the dicing region is denoted by W₀, a width W₁ of the groove 14 may be smaller than the W₀, for example, 2% to 50% of the W₀. The width W₁ of the groove 14 may be in the range of, for example, 2 μm to 10 μm. A beam diameter D₁ of the first laser beam may be determined according to the W₁. The first laser beam L1 can be irradiated, with the center of the beam positioned at the edge portion. Since a picosecond pulse laser is used to form the groove 14, the adhesion of debris to the side walls of the groove 14 is suppressed.

Subsequently, as illustrated in FIG. 1C, a second laser beam L2 is irradiated to an inner region from the edge portion Rz (second step). The inner region is a region which is further away from the element region Rx than the edge portion Rz, and is, for example, a region surrounded by a plurality of edge portions. As a result, in the inner region, the wiring layer between the grooves 14 formed along the edge portions Rz is removed, and an aperture 16 is formed. The groove 14 can serve to prevent a crack from extending toward the element region due to the heat generated by irradiation of the second laser beam L2. The second laser beam L2 can be irradiated, with the center of the beam positioned at the inner region.

The second laser beam L2 may be a laser beam having a Gaussian distribution or a top-hat distribution. The laser beam having a top-hat distribution is a laser beam whose beam intensity is substantially constant within a predetermined range of the distance from the center of the beam. The intensity at the end portions of the top-hat distribution (the shoulder portions where the intensity starts to drop sharply) is not significantly different from the intensity at the center, and is, for example, 90% to 98% of the intensity at the center. For the beam shaping to the top-hat distribution, any known technique, such as a diffractive optical element (DOE) and an aspherical beam shaper, can be used.

The second laser beam L2 may be a nanosecond pulse laser. By using such a laser, the decrease in throughput can be suppressed. In addition, by forming the groove 14 with less adhesion of debris in advance in the first step by irradiation of the first laser beam L1 which is a picosecond pulse laser, the adhesion of debris in the aperture 16 can be suppressed.

A beam diameter D₂ of the second laser beam L2 is determined according to the width W₀ of the dicing region and the width W₁ of the groove 14. The beam diameter D₂ of the second laser beam L2 may be determined to be, for example, 95% to 105% of W₀−2W₁. The W₀−2W₁ is, for example, 5 μm to 40 μm.

By performing the irradiation of the first laser beam L1 and the irradiation of the second laser beam L2, the time required for forming the aperture 16 can be reduced down to, for example, ⅓ or less, as compared to when only performing the irradiation of the first laser beam L1. Also, as compared to when only performing the irradiation of the second laser beam L2, the time required for forming the aperture 16 can be suppressed, for example, not to exceed twice the time, and the increase in the laser processing time can be suppressed while the adhesion of debris can be suppressed or removed.

The spot shapes of the first laser beam L1 and the second laser beam L2 are not limited. The spot shape is a cross-sectional shape perpendicular to the optical axis of the laser beam. The spot shape may be circular, elliptical, or polygonal.

The first laser beam L1 and/or the second laser beam L2 may be irradiated to the dicing region only once or more than once. By irradiating the laser beam separately more than once, the heat influence by laser on the surroundings can be reduced. Therefore, the damage by heat is less likely to occur on the side surfaces of the wiring layer on both sides of the aperture and on the semiconductor layer at the bottom of the aperture. The number of times of irradiation of the laser beam refers to the number of times of scanning of the laser beam to be scanned along the dicing region, and does not mean the number of pulses.

Subsequently, as shown in FIG. 1D, the semiconductor layer 11 exposed at the bottom of the aperture 16 is etched with plasma until reaching the second principal surface 11B (individualization step). As a result, the substrate 10 having a plurality of element regions is divided into a plurality of element chips each having a corresponding element region.

After forming the aperture 16 and before performing the individualization step, a step of cleaning the aperture 16 with plasma may be performed. This plasma is generated, usually, under conditions different from the plasma generated for etching the semiconductor layer 11 in the dicing region. Such a cleaning step is performed, for example, for the purpose of further reducing the residue caused by forming the aperture 16 by laser irradiation. This enables to perform high-quality plasma dicing.

The order of performing the irradiation of the first laser beam L1 in FIG. 1B and the irradiation of the second laser beam L2 in FIG. 1C may be reversed. That is, the first laser beam L1 may be irradiated after the irradiation of the second laser beam L2.

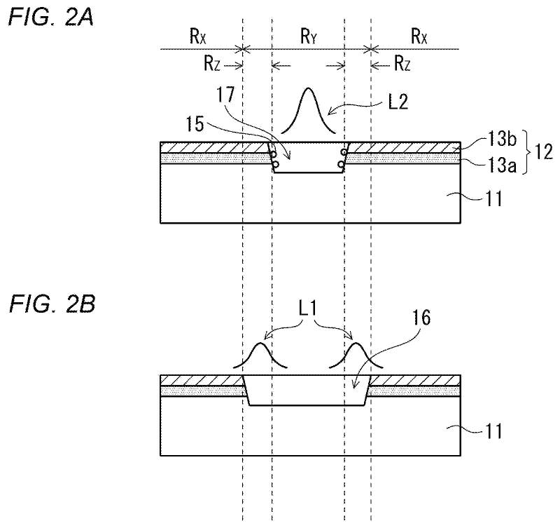

FIGS. 2A and 2B are schematic process cross-sectional views illustrating an element chip manufacturing method according to one embodiment of the present disclosure, which show an example in which the first laser beam L1 is irradiated after the irradiation of the second laser beam L2. The preparation step and the individualization step are similar to in FIGS. 1A and 1D, respectively, and the description thereof will be omitted.

After the preparation step shown in FIG. 1A, as illustrated in FIG. 2A, the second laser beam L2 is irradiated to the inner region, so that a groove 17 exposing the inner region is formed (second step). When the second laser beam L2 is a nanosecond pulse laser, sufficient energy density for removing the wiring layer 12 by ablation cannot be obtained at the beam end of the second laser beam L2, and debris 15 derived from the melted wiring layer may adhere to the side walls of the groove 17. However, the subsequent irradiation of the first laser beam L1 can remove the debris 15 adhering to the side walls of the groove 17.

Subsequently, as shown in FIG. 2B, the first laser beam L1 is irradiated, with the center of the beam positioned at the edge portion, in a region sandwiching the region irradiated with the second laser beam (first step). As a result, the groove 17 is widened into the aperture 16. At this time, the debris adhering to the groove 17 is also removed, and the adhesion of debris and the like to the side walls of the aperture 16 are suppressed. In this case, the beam diameter D₁ of the first laser beam L1 may be smaller than the beam diameter D₂ of the second laser beam

L2.

After the irradiation of the first laser beam L1, the individualization step shown in FIG. 1D is performed, and the substrate 10 is divided into individual element chips.

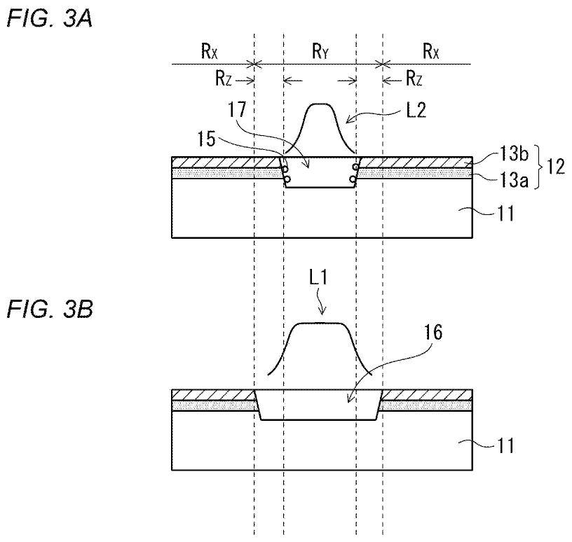

FIGS. 3A and 3B are schematic process cross-sectional views illustrating an element chip manufacturing method according to one embodiment of the present disclosure. In the example shown in FIG. 3, likewise in FIG. 2, the first laser beam L1 is irradiated after the irradiation of the second laser beam L2. The preparation step and the individualization step are similar to in FIGS. 1A and 1D, respectively, and the description thereof will be omitted.

After the preparation step shown in FIG. 1A, as shown in FIG. 3A, the second laser beam L2, which is a nanosecond pulse laser, is irradiated to the inner region, to form a groove 17 exposing the inner region (second step). In the example of FIG. 3A, the width of the aperture (dicing region) to be formed is large, and the second laser beam L2 having a large beam diameter (e.g., having a top-hat intensity distribution) is irradiated. In this case, the energy density at the beam end of the second laser beam L2 tends to be low, and the amount of debris 15 adhering to the side walls of the groove 17 tends to increase.

Subsequently, as shown in FIG. 3B, the first laser beam L1, which is a picosecond pulse laser, is irradiated (first step). The first laser beam L1 is irradiated so as to include the region irradiated with the second laser beam L2. In the example of FIG. 3B, the beam diameter of the first laser beam L1 is larger than that of the second laser beam L2, and the first laser beam L1 is irradiated with the center of the beam positioned at the inner region. As a result, the groove 17 is widened into the aperture 16. At this time, the debris adhering to the groove 17 is also removed, and the adhesion of debris and the like to the side walls of the aperture 16 is suppressed.

In addition, at this time, since the bottom of the groove 17 is also irradiated with the first laser beam L1, the bottom of the groove 17 is also cleaned, and the adhesion of debris and the like to the side walls and the bottom of the aperture 16 is suppressed. In the example of FIG. 3, the beam diameter D₁ of the first laser beam L1 may be 1.02 to 1.1 times as large as the beam diameter D₂ of the second laser beam L2. The beam diameter D₂ of the second laser beam L2 may be determined to be, for example, 102% to 110% of the W₀. The width W₀ of the dicing region may be 5 μm or more and 100 μm or less, and may be 8 μm or more and 65 μm or less. The second step has a significance in cleaning for removing the debris and the like adhering to the side walls of the aperture 16. It is therefore not necessary to set the beam energy density of the first laser beam L1 so high.

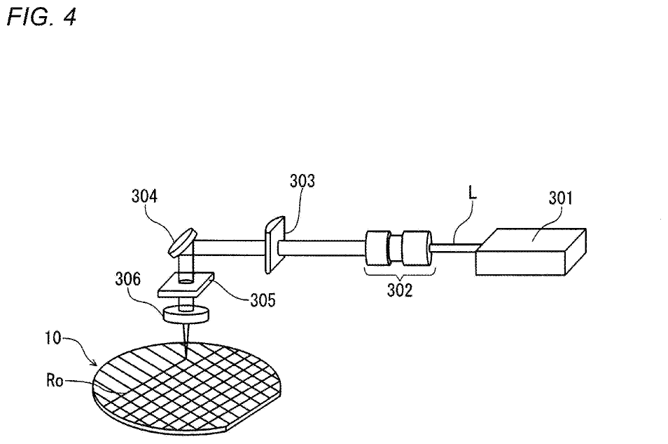

Next, a description will be given of an apparatus for performing the laser grooving step. The laser beam used in the laser grooving step can be obtained using, for example, an optical system as shown in FIG. 4. The optical system of FIG. 4 includes a laser oscillator 301, a zoom expander 302, a cylindrical lens 303 having a semicircular cross section, a bend mirror 304, a DOE 305, and a condenser lens 306. A laser beam L emitted from the laser oscillator 301, which has a Gaussian distribution in all directions, enters the zoom expander 302 having a collimating function. The zoom expander 302 adjusts the beam diameter of the laser beam L to an appropriate value for the DOE 305 which the laser beam transmitted through the cylindrical lens 303 enters. The laser beam L having a circular beam spot output from the zoom expander 302 is converted to have an elliptic beam spot by passing through the cylindrical lens 303, and incident on the bend mirror 304. The DOE 305 converts the spot shape of the laser beam into a rectangular shape. The converted laser beam enters the condenser lens 306, and then, irradiated to the substrate 10. The spot diameter of the laser beam output from the condenser lens 306 is condensed to, for example, 35 μm or less (preferably 20 μm or less) in the width direction of the dicing region, and is irradiated to the substrate (wiring layer) which is an object to be processed.

The DOE 305 can be equipped with a function of converting the spot shape of the laser beam into a desired shape. Therefore, when the DOE 305 has a shape conversion function equivalent to that of the cylindrical lens 303, the cylindrical lens 303 in the optical system of FIG. 4 may be omitted. Furthermore, the DOE can be equipped with a function of converting the beam intensity distribution having a Gaussian distribution to a top-hat distribution.

The laser oscillator 301 is a pulse laser oscillator that emits a pulsed laser beam, and the mechanism for oscillating the laser beam L in a pulsed waveform is not limited. For example, it is possible to adopt a system of turning the beam output ON and OFF with a mechanical shutter, a system of pulse-controlling the excitation source of the laser beam L, a system of switching the beam output, and the like. The laser oscillation mechanism of the laser oscillator 301 is also not limited, and may be, for example, a semiconductor laser using a semiconductor as a laser oscillation medium, a gas laser using a gas, such as carbon dioxide (CO₂), as the medium, a solid laser using YAG, a fiber laser, and the like. The solid laser includes a wavelength-converted green laser and an ultraviolet laser.

The wavelength of the laser beam L is not limited, but is preferably in an ultraviolet region (wavelength: 200 to 400 nm) or a visible region with a relatively short wavelength (wavelength: 400 to 550 nm) because in this case the laser beam L is highly absorbed by the substrate 10. The oscillation frequency of the laser beam L is also not limited, but is, for example, 1 to 200 kHz. A higher oscillation frequency can increase the speed of processing.

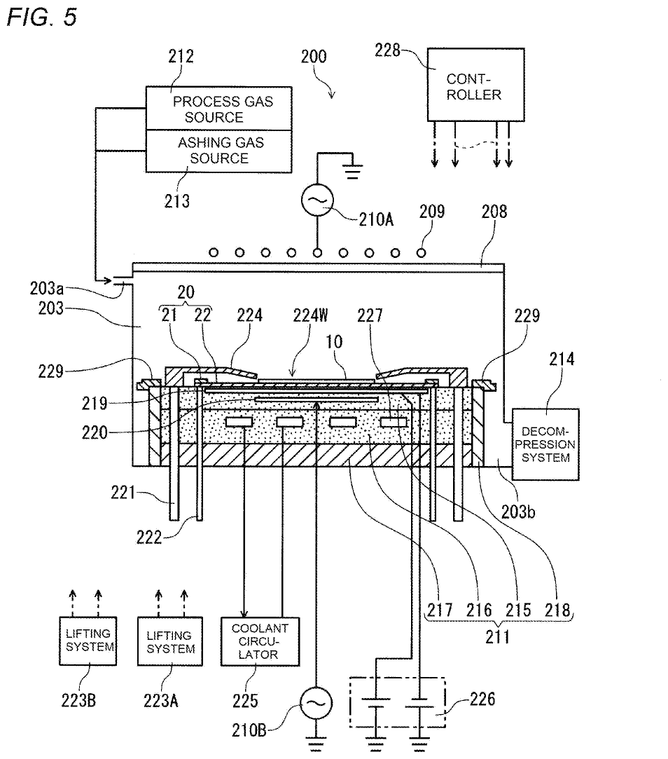

Next, a description will be given of a plasma processing apparatus used in the individualization step, with reference to FIG. 5. It is to be noted, however, that the plasma processing apparatus is not limited thereto.

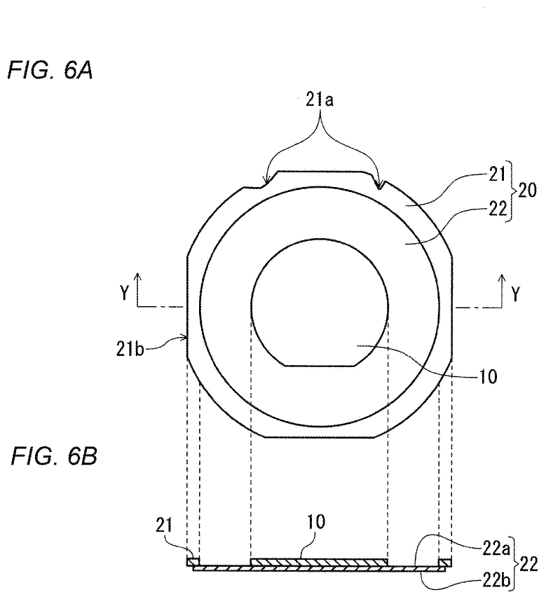

In view of the ease of handling, the individualization step is preferably performed while the substrate 10 is supported by a support member 22 as shown in FIG. 6. At this time, the second principal surface 11B side of the semiconductor layer 11 of the substrate 10 is brought into contact with the support member 22. Any material may be used for the support member 22. Especially when taking into consideration that the substrate 10 is diced while being supported by the support member 22, the support member 22 is preferably made of a flexible resin film, for easy picking up of element chips 10x. At this time, in view of the ease of handling, the support member 22 is fixed to the frame 21. In the following, the frame 21 and the support member 22 fixed to the frame 21 are collectively referred to as a conveying carrier 20. FIG. 6A is a top view of the conveying carrier 20 and the substrate 10 supported by the support member 22, and FIG. 6B is a cross-sectional view thereof taken along a line Y-Y. The support member 22 includes, for example, a surface having an adhesive (adhesive side 22a) and a surface having no adhesive (non-adhesive side 22b). The frame 21 may be provided with a notch 21a or a corner cut 21b for positioning.

A plasma processing apparatus 200 includes a vacuum chamber 203 having a processing space, and has a stage 211 in the processing space. The vacuum chamber 203 is provided with an inlet 203a for introducing gas and an outlet 203b for exhausting gas. The gas inlet 203a is configured to be connected selectively to one of a process gas source 212 and an ashing gas source 213. The gas outlet 203b is connected to a decompression system 214 having a vacuum pump for exhausting the gas within the vacuum chamber 203 to reduce the pressure therein.

On the stage 211, the substrate 10 held on the conveying carrier 20 is placed. The stage 211 is provided at its peripheral portion with a plurality of supports 222 configured to be driven to move up and down by a lifting system 223A. The conveying carrier 20 delivered into the vacuum chamber 203 is passed onto the supports 222, and placed on the stage 211.

Above the stage 211, a cover 224 having a window 224W for covering at least the frame 21 of the conveying carrier 20 and exposing the substrate 10 therefrom is disposed. The cover 224 is coupled with a plurality of lifting rods 221, and driven to move up and down by a lifting system 223B. The vacuum chamber 203 is closed at its upper part with a dielectric member 208, and an antenna 209 is disposed as an upper electrode, above the dielectric member 208. The antenna 209 is connected to a first high-frequency power source 210A.

The stage 211 includes an electrode layer 215, a metal layer 216, and a base table 217 disposed in this order from above, which are surrounded by an outer peripheral portion 218. An outer peripheral ring 229 for protection is disposed on the upper surface of the outer peripheral portion 218. Inside the electrode layer 215, an electrode part (ESC electrode) 219 for electrostatic adsorption, and a high-frequency electrode part 220 connected to the second high-frequency power source 210B are disposed. The ESC electrode 219 is connected to a DC power source 226. By applying a high-frequency power to the high-frequency electrode part 220, the etching step can be performed under application of a bias voltage. A coolant channel 227 for cooling the stage 211 is formed within the metal layer 216, and a coolant is circulated by a coolant circulator 225.

A controller 228 controls the operations of constituent elements of the plasma processing apparatus 200, including the first and second high-frequency power sources 210A and 210B, the process gas source 212, the ashing gas source 213, the decompression system 214, the coolant circulator 225, the lifting systems 223A and 223B, and the electrostatic chuck system.

The plasma is generated under conditions with which the semiconductor layer 11 of the substrate 10 is etched. The etching conditions may be determined appropriately according to the material of the semiconductor layer 11. When the semiconductor layer 11 is made of Si, a Bosch process can be adopted for etching the semiconductor layer 11 along the dicing region Ry. In the Bosch process, a film deposition step, a film etching step, and a Si etching step are sequentially repeated in this order, thereby to deepen the groove in the depth direction.

The film deposition step is carried out, for example, under the following conditions: while C₄F₈ is introduced as a raw material gas at a rate of 150 to 250 sccm, the pressure in the vacuum chamber 203 is controlled to 15 to 25 Pa, with the input power to the antenna 209 from the first high-frequency source 210A set at 1500 to 2500 W, and the input power to the high-frequency electrode part 220 from the second high-frequency power source 210B set at 0 W; the processing time is 5 to 15 seconds.

The film etching step is carried out, for example, under the following conditions: while SF₆ is introduced as a raw material gas at a rate of 200 to 400 sccm, the pressure in the vacuum chamber 203 is controlled to 5 to 15 Pa, with the input power to the antenna 209 from the first high-frequency source 210A set at 1500 to 2500 W, and the input power to the high-frequency electrode part 220 from the second high-frequency power source 210B set at 100 to 300 W; the processing time is 2 to 10 seconds.

The Si etching step is carried out, for example, under the following conditions: while SF₆ is introduced as a raw material gas at a rate of 200 to 400 sccm, the pressure in the vacuum chamber 203 is controlled to 5 to 15 Pa, with the input power to the antenna 209 from the first high-frequency source 210A set at 1500 to 2500 W, and the input power to the high-frequency electrode part 220 from the second high-frequency power source 210B set at 50 to 200 W; the processing time is 10 to 20 seconds.

By repeating the film deposition step, the film etching step, and the Si etching step under the conditions as above, the dicing region Ry can be etched vertically in the depth direction at a rate of approximately 10 μm/min. In generating the plasma, a plurality of kinds of raw material gases may be used in combination. In this case, a plurality of kinds of raw material gases may be introduced with a time lag into the vacuum chamber 203, or a plurality of kinds of raw material gases may be mixed and introduced into the vacuum chamber 203.

In this way, the substrate 10 is divided into a plurality of element chips 10x having the element regions Rx, while being supported by the support member 22. After the plasma dicing step is completed, the plurality of element chips 10x supported by the support member 22 are transferred to the pickup step. In the pickup step, the plurality of element chips 10x are detached from the support member 22.

The plasma dicing step may be followed by ashing or cleaning to remove the resin film remaining on the element chip 10x.

According to the element chip manufacturing method of the present invention, high-quality plasma dicing can be performed. The method is therefore useful as a method for manufacturing element chips from various substrates.

### REFERENCE NUMERALS

10: substrate
10x: element chip

11: semiconductor layer
11A: first principal surface
11B: second principal surface

12: wiring layer
13a: circuit layer
13b: resin layer

14, 17: groove

15: debris

16: aperture
20: conveying carrier

21: frame
21a: notch
21b: corner cut

22: support member
22a: adhesive side
22b: non-adhesive side
200: plasma processing apparatus
203: vacuum chamber
   203a: gas inlet
   203b: gas outlet
208: dielectric member
209: antennas
210A: first high-frequency power source
210B: second high-frequency power source
211: stage
212: process gas source
213: ashing gas source
214: decompression system
215: electrode layer
216: metal layer
217: base table
218: outer peripheral portion
219: ESC electrode
220: high-frequency electrode part
221: lifting rod
222: support
223A, 223B: lifting system
224: cover

224W: window
225: coolant circulator
226: DC power source
227: coolant channel
228: controller
229: outer peripheral ring
301: laser oscillator
302: zoom expander
303: cylindrical lens
304: bend mirror
305: DOE
306: condenser lens
Rx: element region
Ry: dicing region
Rz: edge portion

What is claimed is:

1. An element chip manufacturing method, comprising:
a step of preparing a substrate including a semiconductor layer having a first principal surface and a second principal surface and a wiring layer formed on the semiconductor layer on the first principal surface side, the substrate having a plurality of element regions and a dicing region defining the element regions;
a laser grooving step of irradiating a laser beam from the first principal surface side to the wiring layer at the dicing region, to form an aperture exposing the semiconductor layer in the dicing region; and
a plasma etching step of etching the semiconductor layer exposed from the aperture, with plasma,
the laser grooving step including
a first step of irradiating a first laser beam having a first pulse width, to remove the wiring layer in at least an edge portion of the dicing region, and
a second step of irradiating a second laser beam having a second pulse width which is longer than the first pulse width, to remove the wiring layer in an inner region inside from the edge portion of the dicing region.

2. The element chip manufacturing method according to claim 1, wherein
in the first step, the first laser beam is irradiated, with a beam center positioned at the edge portion, and
in the second step, the second laser beam is irradiated, with a beam center positioned at the inner region.

3. The element chip manufacturing method according to claim 2, wherein the second step is performed after the first step.

4. The element chip manufacturing method according to claim 2, wherein the first step is performed after the second step.

5. The element chip manufacturing method according to claim 4, wherein
in the first step, the first laser beam is irradiated, with the beam center of the first laser beam positioned at the edge portion, in a region sandwiching a region irradiated with the second laser beam, and a beam diameter of the first laser beam is smaller than a beam diameter of the second laser beam.

6. The element chip manufacturing method according to claim 1, wherein
the first step is performed after the second step,
in the first step, the first laser beam is irradiated, with a beam center positioned at the inner region,
in the second step, the second laser beam is irradiated, with a beam center positioned at the inner region, and
a beam diameter of the first laser beam is larger than a beam diameter of the second laser beam.

7. The element chip manufacturing method according to claim 1, wherein
the first pulse width is 100 picoseconds or less, and
the second pulse width is 10 nanoseconds or more.

8. A substrate processing method for forming an aperture at a predetermined region on a substrate including a semiconductor layer having a first principal surface and a second principal surface and a wiring layer formed on the semiconductor layer on the first principal surface side, the aperture being formed to expose the semiconductor layer, the method comprising:
an irradiation step of irradiating a laser beam from the first principal surface side to the wiring layer at the predetermined region;
the irradiation step including a first step of irradiating a first laser beam having a first pulse width, to remove the wiring layer in at least an edge portion of the dicing region, and
a second step of irradiating a second laser beam having a second pulse width which is longer than the first pulse width, to remove the wiring layer in an inner region inside from the edge portion of the predetermined region.
